(19) United States
(12) Patent Application Publication
(10) Pub. No.: US 2008/0143447 A1
(43) Pub. Date: Jun. 19, 2008

(54) HIGH-FREQUENCY OSCILLATOR

(75) Inventors: Shinsuke WATANABE, Tokyo (JP); Takayuki MATSUZUKA, Tokyo (JP); Akira INOUE, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 11/690,255

(22) Filed: Mar. 23, 2007

(30) Foreign Application Priority Data
Dec. 14, 2006 (JP) 2006-336943

(51) Int. Cl. H03B 1/04

(52) U.S. Cl. 331/46; 331/76

(57) ABSTRACT

Provided is a high-frequency oscillator whose output power increases without a change in physical size of the entire high-frequency oscillator and deterioration of a phase noise characteristic. The high-frequency oscillator for harmonic extraction includes: an active element (5); a fundamental reflection stub (9) provided on a signal line located on an output side of the active element (5); an output terminal (4); and a harmonic impedance converting circuit (3) interposed between the fundamental reflection stub (9) and the output terminal (4), for converting a harmonic output terminal side load impedance into an optimum value for maximizing harmonic output power, the optimum value being obtained in advance.

### BACKGROUND OF THE INVENTION

1. Field of the Invention

The present invention relates to a high-frequency oscillator, and more particularly, to a high-frequency oscillator operated in a microwave or millimeter wave region.

2. Description of the Related Art

With the widespread use of a mobile communication device represented by a mobile telephone and a consumer radar represented by a vehicle-mounted radar, a reduction in size of an oscillator and an improvement in performance thereof are increasingly demanded.

A fundamental oscillator using transistor includes a transistor for amplifying a noise caused in an inner portion of the circuit, a bias circuit for the transistor, an emitter line for causing a feedback of an electrical signal, a resonance circuit for amplifying only a noise having a specific frequency and an output terminal. A noise signal caused in the inner portion of the circuit is inputted to the transistor and amplified thereby. After that, the noise signal is returned to the resonance circuit by the feedback from an emitter of the transistor or the reflection caused by impedance mismatching in the output terminal of the circuit. The returned noise signal is inputted to the transistor again and amplified thereby. The noise signal repeatedly amplified as described above is oscillated to the outside of the circuit.

In order to generate an electrical signal having a desirable frequency with a preferable characteristic in the fundamental oscillator, it is necessary for the transistor to have a sufficient gain at the desirable frequency. However, the gain of the transistor normally reduces as the frequency becomes higher. Therefore, a harmonic extraction oscillator is normally used. According to the harmonic extraction oscillator, an electrical signal whose frequency is an integral submultiple of a desirable frequency is oscillated and a harmonic signal is extracted from the output terminal. The harmonic extraction oscillator is an oscillator having a preferable characteristic because requirements on a high-frequency characteristic to the transistor are not tighter than those to the fundamental oscillator.

An example of a harmonic extraction method is a method using a fundamental reflection stub. An end open stub corresponding to one-quarter of a wavelength of a fundamental oscillated in the inner portion of the circuit is provided on a side closer to the output terminal than the transistor. The fundamental traveling from the transistor to the stub is reflected again to the transistor and the resonance circuit by the stub. On the other hand, a second harmonic travels to the output terminal and is extracted to the outside because the stub acts as an open circuit to the second harmonic (see, for example, Hamano. S, two others, “A Low Phase Noise 19 GHz-band VCO using Two Different Frequency Resonators”, IEEE MTT-S Int. Microwave Symp. Digest, June 2003, p. 2189-2191).

Another example of the harmonic extraction method is a method using a push-push type. Two oscillators are prepared and oscillated in opposite phases to combine electrical signals with each other on the output side. At this time, fundamentals are combined with each other in opposite phases and second harmonics are combined with each other in the same phase. Therefore, the fundamentals cancel each other out, so the fundamentals are not outputted to the outside and only the second harmonics are extracted to the outside (see, for example, Baeyens. Y, one other, “A monolithic integrated 150 GHz SiGe HBT Push-Push VCO with simultaneous differential V-band output”, IEEE MTT-S Int. Microwave Symp. Digest, June 2003, p. 877-880).

In order to control output power of the oscillator and a phase noise thereof the resonance circuit is adjusted. For example, when an oscillator having a preferable phase noise characteristic in which a signal spectrum has a delta function shape is to be manufactured, a resonance circuit using a dielectric roughly coupled to a signal line or a coupling line is employed. In this case, although a signal loss increases to reduce the output power, a change in oscillation frequency which is caused by phase variation is suppressed to improve the phase noise characteristic. When an oscillator whose output power is large is to be manufactured, a resonance circuit using a simple signal line is employed. Therefore, the oscillation frequency is likely to change, so the phase noise characteristic deteriorates. However, a signal loss in the resonance circuit is suppressed to increase the output power.

When a physical size of the entire circuit of the oscillator is determined to some degree, there is a tradeoff relationship between the phase noise characteristic and the output power characteristic. When one of the characteristics is improved, the other characteristic deteriorates. Both the characteristics can be simultaneously improved by using a resonance circuit whose loss is low and physical size is large. However, there are problems in that a material cost increases, a manufacturing time lengthens, the physical size of the entire oscillator increases, and it is difficult to adjust the oscillation frequency to a desirable frequency. Therefore, a current mobile communication device or a current vehicle-mounted radar mainly employs a method of using an oscillator whose electrical design is focused on the phase noise characteristic and whose physical size is small and using an amplifier to increase output power of the oscillator.

However, because of the addition of the amplifier, there are problems in that the cost increases, the manufacturing time lengthens, the physical size of the entire system becomes larger, and power consumption increases.

### SUMMARY OF THE INVENTION

Therefore, an object of the present invention is to provide a high-frequency oscillator whose output power increases without a change in physical size of the entire high-frequency oscillator and deterioration of a phase noise characteristic.

According to the present invention, there is provided a high-frequency oscillator for harmonic extraction, including: an active element; a fundamental reflection stub provided on a signal line located on an output side of the active element; an output terminal; and a harmonic impedance converting circuit interposed between the fundamental reflection stub and the output terminal, for converting a harmonic output terminal side load impedance into an optimum value for maximizing harmonic output power, the optimum value being obtained in advance.

According to an effect obtained by the high-frequency oscillator of the present invention, the harmonic impedance converting circuit for converting a harmonic output terminal side load impedance into an optimum value calculated by a load pull oscillation simulation or a source pull oscillation simulation is incorporated, so the harmonic output power to be extracted can be increased without the deterioration of the phase noise characteristic.

### BRIEF DESCRIPTION OF THE DRAWINGS

FIG. 1 is a block diagram showing a structure of a high-frequency oscillator according to Embodiment 1 of the present invention;

FIGS. 2A to 2D show examples of a harmonic impedance converting circuit according to Embodiment 1 of the present invention;

FIG. 3 shows an example of the harmonic impedance converting circuit for adjusting a second harmonic output terminal side load impedance by voltage control;

FIG. 4 is a block diagram showing a structure of a high-frequency oscillator according to Embodiment 2 of the present invention;

FIG. 5 is a block diagram showing a structure of a high-frequency oscillator according to Embodiment 3 of the present invention;

FIGS. 6A and 6B are circuit diagrams showing examples of a fundamental open harmonic impedance converting circuit according to Embodiment 3 of the present invention;

FIG. 7 is a block diagram showing a structure of a high-frequency oscillator according to Embodiment 4 of the present invention;

FIG. 8 is a block diagram showing a structure of a high-frequency oscillator according to Embodiment 5 of the present invention;

FIG. 9 is a block diagram showing a structure of a high-frequency oscillator used for comparison;

FIGS. 10A to 10C show results obtained by simulation on an oscillation frequency, output power, a phase noise, and a second harmonic load impedance of the high-frequency oscillator used for comparison;

FIGS. 11A to 11C show results obtained by simulation on an oscillation frequency, output power, a phase noise, and a second harmonic load impedance of the high-frequency oscillator according to Embodiment 5 of the present invention; and

FIG. 12 is a block diagram showing a structure of a high-frequency oscillator according to Embodiment 6 of the present invention.

### DETAILED DESCRIPTION OF THE PREFERRED EMBODIMENTS

A vocabulary necessary to describe a high-frequency oscillator according to the present invention will be shown. A resonance circuit side load impedance when a resonance circuit is viewed from an input end of an active element in an inner portion of the circuit is expressed by Zsource. An output terminal side load impedance when an output terminal is viewed from an output end of the active element is expressed by Zload. An input impedance of the active element is expressed by Γin. An output impedance of the active element is expressed by Γout.

With respect to an impedance related to a fundamental, a fundamental resonance circuit side load impedance is expressed by Zsource(f) and a fundamental output terminal side load impedance is expressed by Zload(f). With respect to an impedance related to a second harmonic, a second harmonic resonance circuit side load impedance is expressed by Zsource(2f) and a second harmonic output terminal side load impedance is expressed by Zload(2f).

### Embodiment 1

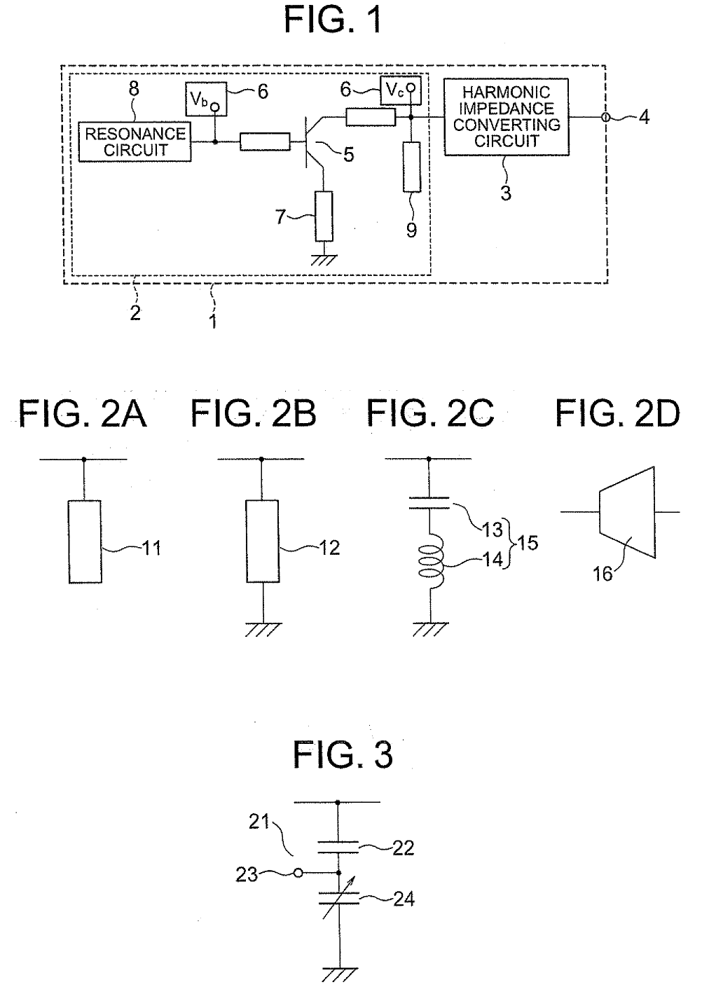

FIG. 1 is a block diagram showing a structure of a high-frequency oscillator according to Embodiment 1 of the present invention.

An high-frequency oscillator 1 according to Embodiment 1 of the present invention includes a second harmonic extraction oscillator 2 serving as a harmonic extraction oscillator, a harmonic impedance converting circuit 3 for adjusting the second harmonic output terminal side load impedance Zload(2f, and a signal output terminal 4.

The second harmonic extraction oscillator 2 includes a transistor 5 serving as an active element for amplifying a noise caused in the inner portion of the circuit, a bias supplying section 6 for supplying biases Vb and Vc to the transistor 5, an emitter line 7 for causing a feedback of an electrical signal, a resonance circuit 8 for amplifying only a noise having a specific frequency, and a fundamental reflection stub 9 for reflecting a fundamental.

In the second harmonic extraction oscillator 2, a noise signal caused in the inner portion of the circuit is inputted to the transistor 5 and amplified thereby. After that, the noise signal is returned to the resonance circuit 8 by the feedback from the emitter line 7 of the transistor 5 or the reflection from the fundamental reflection stub 9. The returned noise signal is inputted to the transistor 5 again and amplified thereby. A second harmonic signal obtained by the above-mentioned repeated amplification is oscillated to the outside of the second harmonic extraction oscillator 2.

In the second harmonic extraction oscillator 2, the fundamental does not travel to an output side of the fundamental reflection stub 9. Therefore, even when an arbitrary circuit is provided on the output side of the fundamental reflection stub 9, the fundamental output terminal side load impedance Zload(f) as viewed from the transistor 5 does not change. Thus, the harmonic impedance converting circuit 3 is provided on the output side of the fundamental reflection stub 9, so the second harmonic output terminal side load impedance Zload(2f) can be adjusted to an optimum value for maximizing second harmonic output power.

FIG. 2A to 2D show examples of the harmonic impedance converting circuit according to Embodiment 1 of the present invention. As shown in FIG. 2A, an end open stub 11 is used as the harmonic impedance converting circuit. As shown in FIG. 2B, an end short circuit stub 12 is used as the harmonic impedance converting circuit. As shown in FIG. 2C, an LC circuit 15 composed of a capacitor 13 and an inductor 14 is used as the harmonic impedance converting circuit. As shown in FIG. 2D, a line 16 whose line width increases in a signal traveling direction is used as the harmonic impedance converting circuit.

As long as the harmonic impedance converting circuit 3 according to Embodiment 1 is a circuit capable of converting the second harmonic output terminal side load impedance Zload(2f) into the optimum value for maximizing the second harmonic output power, a circuit configuration thereof may be freely selected. A plurality of harmonic impedance converting circuits, each of which is the example of the harmonic impedance converting circuit 3 as shown in any one of FIGS. 2A to 2D, may be used. A combination of harmonic impedance converting circuits 3 which are different from each other may be used.

Circuit constants of the harmonic impedance converting circuit 3 according to Embodiment 1 are adjusted such that the second harmonic output terminal side load impedance Zload(2f) becomes an optimum value calculated through execution of a load pull oscillation simulation or a source pull oscillation simulation.

The optimum value of the second harmonic output terminal side load impedance Zload(2f) for maximizing the second harmonic output power is a complex conjugate impedance of the output impedance Γout when the transistor is in an oscillation state. The output impedance Γout is not an output impedance measured when a single-frequency signal is inputted but the output impedance Γout related to the second harmonic when the fundamental is in an oscillation state. When an oscillated fundamental exists in an inner portion of the transistor 5, the output impedance Γout related to the second harmonic is different from the output impedance Γout related to a small signal. Therefore, it is effective that a load pull oscillation simulation or a source pull oscillation simulation for analyzing an oscillation state is performed to calculate the optimum value of the second harmonic output terminal side load impedance Zload(2f).

FIG. 3 shows an example of the harmonic impedance converting circuit for adjusting the second harmonic output terminal side load impedance Zload(2f) by voltage control.

A harmonic impedance converting circuit 21 shown in FIG. 3 includes a variable capacitor 22, a voltage terminal 23, and a DC blocking capacitor 24. In the harmonic impedance converting circuit 21, a capacitance of the variable capacitor 22 is changed based on a voltage applied from the voltage terminal 23. Therefore, the impedance of the harmonic impedance converting circuit 21 can be changed to adjust the second harmonic output terminal side load impedance Zload(2f) to the optimum value.

When the actual high-frequency oscillator 1 is to be manufactured, there are factors such as an error between a transistor model and the actual transistor 5, a calculation error of a harmonic balance simulation, and an error of an electromagnetic field analysis simulation of the harmonic impedance converting circuit 3. Therefore, it is difficult to manufacture the high-frequency oscillator 1 in which the second harmonic output terminal side load impedance Zload(2f) is completely equal to the optimum value. When the second harmonic extraction oscillator 2 is a voltage control oscillator whose oscillation frequency is variable, the optimum value of the second harmonic output terminal side load impedance Zload(2f) is changed with a change in oscillation frequency.

Thus, a circuit whose impedance can be controlled from the outside is used as the harmonic impedance converting circuit 3, so the second harmonic output terminal side load impedance Zload(2f) can be corrected to the optimum value in view of a change in design error or osculation frequency.

Next, the technical meaning that the harmonic impedance converting circuit 3 is added to the high-frequency oscillator 1 will be described.

In the case of an amplifier, a matching circuit for obtaining a complex conjugate relationship between an input side load impedance and an input impedance of the active element, and a matching circuit for obtaining a complex conjugate relationship between an output side load impedance and an output impedance of the active element are normally provided to perform complex conjugate matching, thereby realizing increases in output and gain.

In the case of the amplifier, the input side load impedance at a harmonic frequency is normally short-circuited and the output side load impedance at the harmonic frequency is adjusted to an inverse class-F impedance or a class-F impedance, thereby realizing further increases in output and gain.

In the case of a multiplexer, the input side load impedance related to the input fundamental is adjusted to a complex conjugate impedance and the output side load impedance related thereto is short-circuited. The input side load impedance related to the harmonic is short-circuited and the output side load impedance related thereto is adjusted to a complex conjugate impedance. Therefore, the harmonic output power can be normally increased.

As described above, the adjustment of the harmonic impedance or the matching thereof is a general method in the case of other circuits. Therefore, even in the case of the harmonic extraction oscillator, it is reasonably expected that a harmonic impedance matching circuit be further provided to increase the harmonic output power.

On the other hand, in the case of the fundamental oscillator, as described in JP 2000-114870 A, the harmonic is an unnecessary signal by which the characteristic of the fundamental is deteriorated, so a circuit for removing the harmonic is devised.

However, up to now, when the harmonic output power of the harmonic extraction oscillator is to be increased, no importance is put on harmonic impedance matching. The first reason of this is as follows. The characteristics of the oscillator are generally determined based on the fundamental load impedance, so the focus is put on the adjustment of the fundamental load impedance so as to obtain a desirable oscillation frequency and a desirable phase noise characteristic.

The second reason is that it is difficult to provide the harmonic matching circuit on the input side of the transistor after the completion of the oscillator. This is because, the oscillator does not include an input terminal, so it is necessary to change an inner structure of the oscillator in order to adjust a harmonic input terminal side load impedance.

The third reason is that it is difficult to perform complex conjugate matching with respect to the harmonic output terminal side load impedance after the completion. This is because, when a direct current bias is applied to the oscillator a harmonic signal generates, so it is difficult to measure an output impedance of the transistor in a state in which the direct current bias is applied.

The fourth reason is that, even when a small signal S-parameter or a large signal S-parameter of the transistor which is in a non-oscillation state is measured, the measured parameter S-parameter is different from an S-parameter of the transistor which is in an oscillation state, so a matching point of the transistor which is in the oscillation state cannon be found. This is because, a fundamental signal and a harmonic signal which are in the large signal state are mixed in the transistor which is in the oscillation state, of the harmonic extraction oscillator.

However, the inventors of the present invention have performed a harmonic balance simulation with respect to the first reason. As a result, it is found that the harmonic output power of the oscillator is significantly varied with a change in harmonic load impedance. With respect to the second reason and the third reason, when the harmonic impedance converting circuit used for the amplifier or the multiplexer is provided in the inner portion of the oscillator at the stage of designing the oscillator, it is found that an oscillator for generating a harmonic signal of high output power can be manufactured. With respect to the fourth reason, a load pull oscillation simulation and a source pull oscillation simulation are performed to simulate oscillation states at all values of the harmonic load impedance, and a harmonic load impedance for maximizing the harmonic output power is calculated based on the result obtained by simulations. As a result, it is found that the impedance of the harmonic impedance converting circuit is determined.

When the harmonic output power is to be increased, it is necessary to prevent the deterioration of the phase noise characteristic. This is because the oscillation frequency of the oscillator and the phase noise characteristic thereof are generally determined based on the fundamental load impedance. Therefore, when the harmonic load impedance is adjusted while the fundamental load impedance is held to an impedance for obtaining a desirable phase noise characteristic, the output power can be increased without the deterioration of the phase noise characteristic.

That is, according to the high-frequency oscillator 1 of the present invention, the harmonic impedance converting circuit 3 for converting the second harmonic output terminal side load impedance and the second harmonic resonance circuit side load impedance into the optimum values calculated by the load pull oscillation simulation and the source pull oscillation simulation is incorporated. Thus, the output power of the extracted harmonic can be increased without the deterioration of the phase noise characteristic.

### Embodiment 2

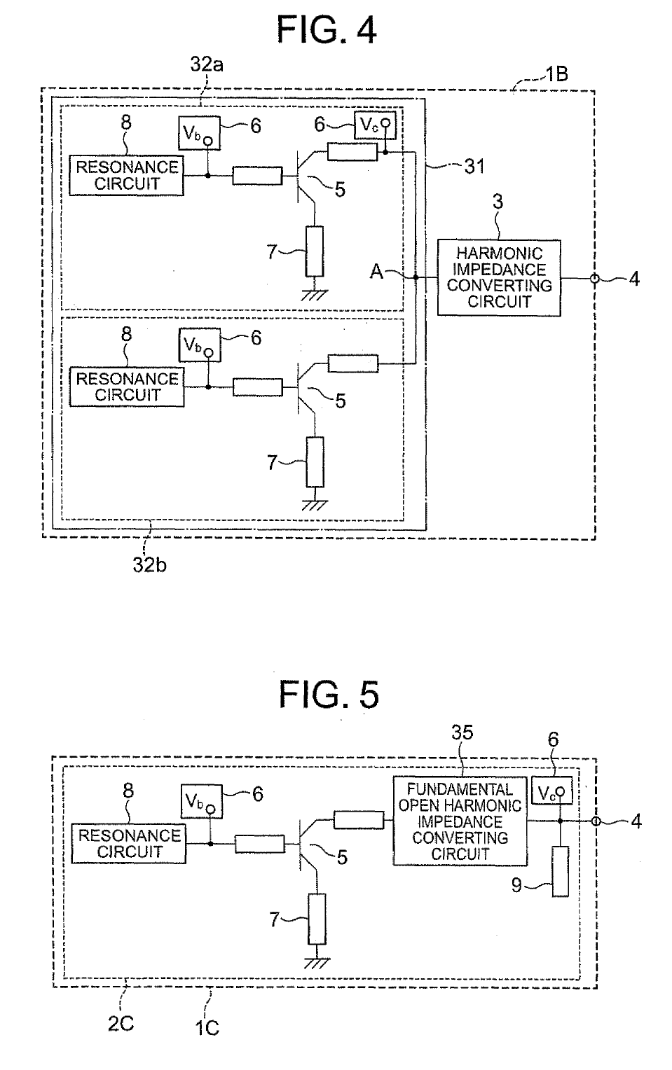

FIG. 4 is a block diagram showing a structure of a high-frequency oscillator according to Embodiment 2 of the present invention.

A high-frequency oscillator 1B according to Embodiment 2 of the present invention is different from the high frequency oscillator 1 according to Embodiment 1 in that a push-push oscillator 31 is provided instead of the second harmonic extraction oscillator 2. The other structures are identical to those of Embodiment 1, so the same portions are denoted by the same reference numerals and the description thereof is omitted here.

The push-push oscillator 31 according to Embodiment 2 of the present invention includes two oscillators 32a and 32b. The oscillators 32a and 32b include output terminals connected with each other at a connection point (shown as point “A” in FIG. 4). Outputs of the oscillators 32a and 32b have opposite phases to each other in the case of the fundamental, and have the same phase in the case of the second harmonic.

When the outputs of the oscillators 32a and 32b are combined with each other, the fundamentals cancel each other out, so the fundamentals are not outputted to the outside and only the second harmonics are extracted thereto.

Therefore, the harmonic impedance converting circuit 3 described in Embodiment 1 is interposed between the point “A” and the output terminal 4, with the result that the second harmonic output terminal side load impedance can be converted into an optimum value for increasing the second harmonic output power.

### Embodiment 3

FIG. 5 is a block diagram showing a structure of a high-frequency oscillator according to Embodiment 3 of the present invention.

A high-frequency oscillator 1C according to Embodiment 3 of the present invention is different from the high frequency oscillator 1 according to Embodiment 1 in that a second harmonic extraction oscillator 2C is used instead of the second harmonic extraction oscillator 2, and the harmonic impedance converting circuit 3 is omitted because of this. The second harmonic extraction oscillator 2C is different from the second harmonic extraction oscillator 2 described in Embodiment 1 in that a fundamental open harmonic impedance converting circuit 35 is further provided thereto. The other structures are identical to those of Embodiment 1, so the same portions are denoted by the same reference numerals and the description thereof is omitted here.

The fundamental open harmonic impedance converting circuit 35 according to Embodiment 3 of the present invention is a circuit for adjusting the second harmonic output terminal side load impedance Zload(2f) without the influence on the fundamental output terminal side load impedance Zload(f).

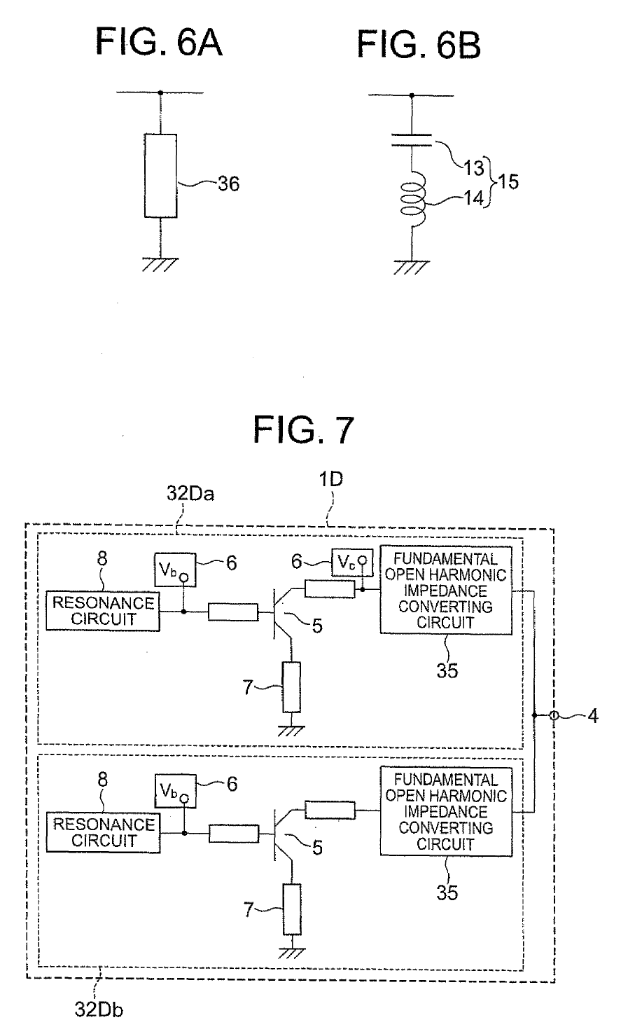

FIGS. 6A and 6B are circuit diagrams showing examples of the fundamental open harmonic impedance converting circuit 35 according to Embodiment 3 of the present invention.

As shown in FIG. 6A, an end short circuit stub 36 which has a line length corresponding to a sum of a one-quarter of a wavelength of the fundamental and an integral multiple of a half wavelength of the fundamental and is opened with respect to the fundamental is used as the fundamental open harmonic impedance converting circuit. As shown in FIG. 6B, the LC circuit 15 which is composed of the capacitor 13 and the inductor 14 and opened with respect to the fundamental by the adjustment of the capacitance and the inductance is used as the fundamental open harmonic impedance converting circuit. When the fundamental open harmonic impedance converting circuit 35 which acts as an open circuit with respect to the fundamental is connected in parallel with a signal line, the second harmonic output terminal side load impedance Zload(2f) can be adjusted without the influence on the fundamental output terminal side load impedance Zload(f).

Therefore, the fundamental open harmonic impedance converting circuit 35 can be provided at an arbitrary position on the output terminal 4 side of the transistor 5.

When the harmonic impedance converting circuit 3 according to Embodiment 1 is provided at the arbitrary position on the output terminal 4 side of the transistor 5, the second harmonic output terminal side load impedance Zload(2f) can be adjusted. However, the fundamental output terminal side load impedance Zload(f) is simultaneously changed. Therefore, the harmonic impedance converting circuit 3 can be provided only on the output terminal 4 side of the fundamental reflection stub 9.

On the other hand, the fundamental open harmonic impedance converting circuit 35 according to Embodiment 3 acts the open circuit with respect to the fundamental. Therefore, the fundamental open harmonic impedance converting circuit 35 can be provided at the arbitrary position on the output terminal 4 side of the transistor 5, so the degree of freedom of a design becomes larger.

### Embodiment 4

FIG. 7 is a block diagram showing a structure of a high-frequency oscillator according to Embodiment 4 of the present invention.

A high-frequency oscillator 1D according to Embodiment 4 of the present invention is different from the high frequency oscillator 1B according to Embodiment 2 in that oscillators 32Da and 32Db are used instead of the oscillators 32a and 32b and the harmonic impedance converting circuit 3 is omitted because of this. The other structures are identical to those of Embodiment 2, so the same portions are denoted by the same reference numerals and the description thereof is omitted here.

The oscillators 32Da and 32Db according to Embodiment 4 of the present invention are different from the oscillators 32a and 32b described in Embodiment 2 in that the fundamental open harmonic impedance converting circuit 35 is further provided in each of the oscillators 32a and 32b. The other structures are identical to those of Embodiment 2, so the same portions are denoted by the same reference numerals and the description thereof is omitted here.

The fundamental open harmonic impedance converting circuit 35 according to Embodiment 4 of the present invention is identical to the fundamental open harmonic impedance converting circuit 35 according to Embodiment 3. Therefore, even when the fundamental open harmonic impedance converting circuit 35 is connected in parallel with a signal line located on the output terminal 4 side of the transistor 5, the second harmonic output terminal side load impedance Zload(2f) can be adjusted without the influence on the fundamental output terminal side load impedance Zload(f).

Thus, even in the case the push-push type is used for harmonic extraction, when the fundamental open harmonic impedance converting circuit 35 capable of adjusting the harmonic output terminal side load impedance without the influence on the fundamental output terminal side load impedance is applied, the fundamental open harmonic impedance converting circuit 35 can be provided at the arbitrary position on the output terminal 4 side of the transistor 5, so the degree of freedom of the design becomes larger.

### Embodiment 5

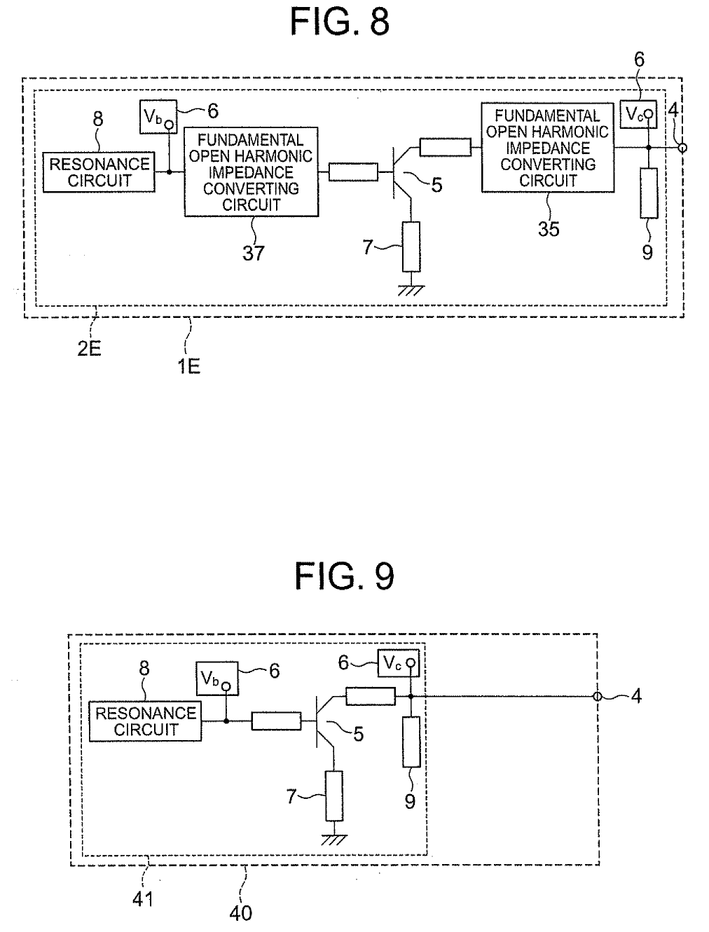

FIG. 8 is a block diagram showing a structure of a high-frequency oscillator according to Embodiment 5 of the present invention.

A high-frequency oscillator 1E according to Embodiment 5 of the present invention is different from the high frequency oscillator 1C according to Embodiment 3 in that a second harmonic extraction oscillator 2E is used instead of the second harmonic extraction oscillator 2C. The other structures are identical to those of Embodiment 3, so the same portions are denoted by the same reference numerals and the description thereof is omitted here.

The second harmonic extraction oscillator 2E according to Embodiment 5 of the present invention is different from the second harmonic extraction oscillator 2C according to Embodiment 3 in that a fundamental open harmonic impedance converting circuit 37 is further provided thereto. The other structures are identical to those of Embodiment 2, so the same portions are denoted by the same reference numerals and the description thereof is omitted here.

The fundamental open harmonic impedance converting circuit 37 according to Embodiment 5 of the present invention is provided on the resonance circuit 8 side of the transistor 5. Therefore, the second harmonic resonance circuit side load impedance Zsource(2f) can be adjusted without the influence on the fundamental resonance circuit side load impedance Zsource(f).

The second harmonic output power is influenced by not only the second harmonic output terminal side load impedance Zload(2f) but also the second harmonic resonance circuit side load impedance Zsource(2f) as viewed from the transistor 5. The optimum value of the second harmonic resonance circuit side load impedance Zsource(2f) in the case where the second harmonic output power becomes maximum is an impedance close to a short circuit impedance as in the case of the amplifier or the multiplexer.

Next, results obtained by simulation on characteristics of the high-frequency oscillator 1E according to Embodiment 5 will be described.

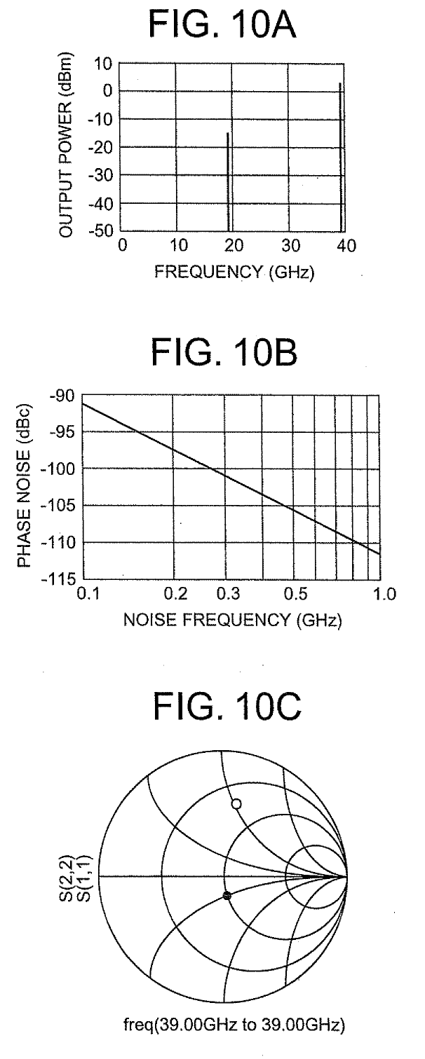

First, characteristics of a high-frequency oscillator 40 shown in FIG. 9 are simulated for comparison. The high-frequency oscillator 40 includes a harmonic extraction oscillator 41 designed to have a simplest structure by focusing on output power using the fundamental reflection stub 9. FIGS. 10A to 10C show results obtained by simulation on an oscillation frequency, output power, a phase noise, and a second harmonic load impedance of the high-frequency oscillator 40. The second harmonic resonance circuit side load impedance Zsource(2f) is expressed by a white circle and the second harmonic output terminal side load impedance Zload(2f) is expressed by a black circle.

From the results obtained by simulation, in the case of the high-frequency oscillator 40, a second harmonic frequency is 39.04 GHz, second harmonic output power is 3.514 dBm, and a phase noise at a frequency detuned from the second harmonic frequency by 1 MHz is −112.4 dBc/Hz.

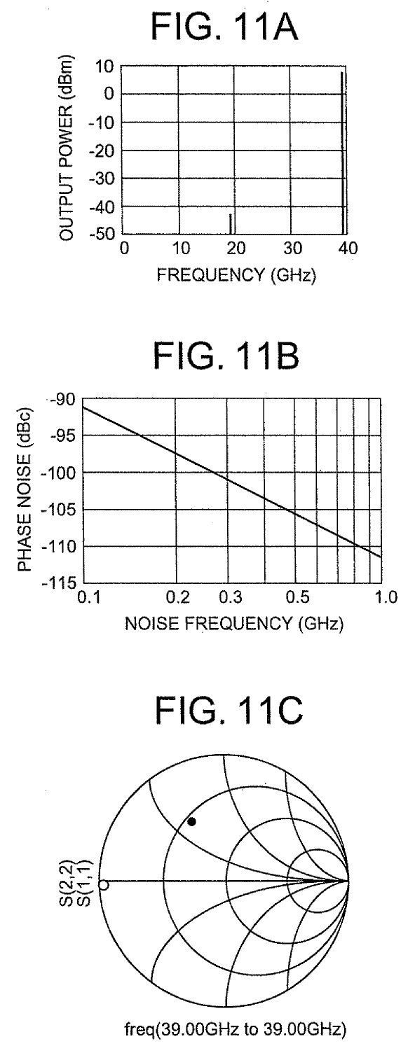

Next, the characteristics of the high-frequency oscillator 1E according to EmbodimentS are simulated. FIGS. 11A to 11C show results obtained by simulation on an oscillation frequency, output power a phase noise, and a second harmonic load impedance of the high-frequency oscillator 1E according to Embodiment 5. The end short circuit stub is used as the fundamental open harmonic impedance converting circuit 37 and a bias blocking capacitor is further provided.

The optimum value of the second harmonic resonance circuit side load impedance Zsource(2f) and the optimum value of the second harmonic output terminal side load impedance Zload(2f) in the case where the second harmonic output power becomes maximum are calculated by a load pull oscillation simulation and a source pull oscillation simulation. Each of the second harmonic resonance circuit side load impedance Zsource(2f) and the second harmonic output terminal side load impedance Zload(2f) are adjusted to the optimum value by the adjustment of the end short circuit stub and an attachment position thereof.

From the results obtained by simulation, in the case of the high-frequency oscillator 1E according to Embodiment 5, a second harmonic frequency is 39.01 GHz, second harmonic output power is 8.412 dBm, and a phase noise at a frequency detuned from the second harmonic frequency by 1 MHz is −113.6 dBc/Hz.

According to the high-frequency oscillator 1E of Embodiment 5, the fundamental open harmonic impedance converting circuit 37 is provided on the resonance circuit 8 side of the transistor 5 of the second harmonic extraction oscillator 2E. Therefore, the second harmonic resonance circuit side load impedance can be adjusted to an optimum value for increasing the second harmonic output power. Thus, the second harmonic output power can be further increased without deterioration of a phase noise characteristic.

### Embodiment 6

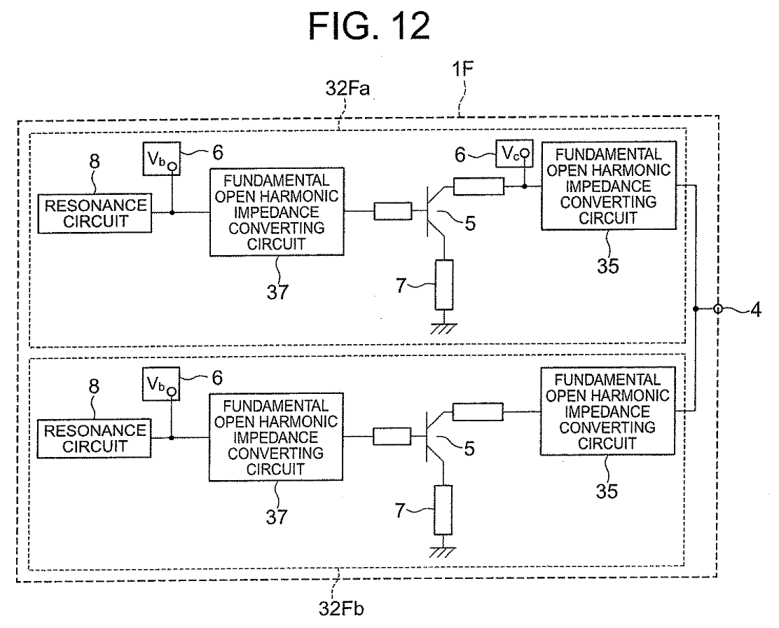

FIG. 12 is a block diagram showing a structure of a high-frequency oscillator according to Embodiment 6 of the present invention.

A high-frequency oscillator 1F according to Embodiment 6 of the present invention is different from the high frequency oscillator 1D according to Embodiment 4 in that two oscillators 32Fa and 32Fb are used instead of the oscillators 32Da and 32Db. The other structures are identical to those of Embodiment 4, so the same portions are denoted by the same reference numerals and the description thereof is omitted here.

The oscillators 32Fa and 32Fb according to Embodiment 6 of the present invention are different from the two oscillators 32Da and 32Db described in Embodiment 4 in that the fundamental open harmonic impedance converting circuit 37 is further provided in each of the oscillators 32Da and 32Db. The other structures are identical to those of Embodiment 4, so the same portions are denoted by the same reference numerals and the description thereof is omitted here.

The fundamental open harmonic impedance converting circuit 37 according to Embodiment 6 of the present invention is identical to the fundamental open harmonic impedance converting circuit 37 according to Embodiment 5.

According to the high-frequency oscillator 1F of Embodiment 6, the fundamental open harmonic impedance converting circuit 37 is provided on the resonance circuit 8 side of the transistor 5 of each of the two oscillators 32Fa and 32Fb. Therefore, the second harmonic resonance circuit side load impedance can be adjusted to an optimum value for increasing the second harmonic output power. Thus, the second harmonic output power can be further increased without the deterioration of the phase noise characteristic.

What is claimed is:

1. A high-frequency oscillator for harmonic extraction, comprising:
an oscillator having a fundamental reflection stub provided on a signal line located on an output side of an active element; and
a harmonic impedance converting circuit for converting a harmonic output terminal side load impedance into an optimum value for maximizing harmonic output power, the optimum value being obtained in advance.

2. The high-frequency oscillator for harmonic extraction according to claim 1, wherein the harmonic impedance converting circuit is interposed between the fundamental reflection stub and an output terminal.

3. The high-frequency oscillator for harmonic extraction according to claim 1, wherein the harmonic impedance converting circuit is provided on the signal line located on the output side of the active element and converts only the harmonic output terminal side load impedance without influencing fundamental output terminal side load impedance.

4. The high-frequency oscillator for harmonic extraction according to claim 1, wherein the harmonic impedance converting circuit is provided on a signal line located on an input side of the active element and converts only the harmonic resonance circuit side load impedance without influencing fundamental resonance circuit side load impedance.

5. A high-frequency oscillator of a push-push type, comprising:
two oscillators whose output side signal lines are connected with each other, for outputting fundamentals whose frequencies are equal to each other at opposite phases; and
a harmonic impedance converting circuit for converting a harmonic output terminal side load impedance into an optimum value for maximizing harmonic output power, the optimum value being obtained in advance.

6. The high-frequency oscillator of a push-push type according to claim 5, wherein the harmonic impedance converting circuit is interposed between a point connected between output terminals of the two oscillators and an output terminal.

7. The high-frequency oscillator of a push-push type according to claim 5, wherein the harmonic impedance converting circuit is provided on a signal line located on an output side of an active element of each of the oscillators respectively and converts only a harmonic output terminal side load impedance without influencing fundamental output terminal side load impedance.

8. The high-frequency oscillator of a push-push type according to claim 5, wherein the harmonic impedance converting circuit is provided on a signal line located on an input side of the active element of each of the oscillators respectively and converts only a harmonic resonance circuit side load impedance without influencing fundamental resonance circuit side load impedance.
